(19) United States
(12) Patent Application Publication
(10) Pub. No.: US 2015/0039270 A1
(43) Pub. Date: Feb. 5, 2015

(54) METHOD FOR INSPECTING DEFECTS OF SOLAR CELLS AND SYSTEM THEREOF

(71) Applicant: Industrial Technology Research Institute, Hsinchu (TW)

(72) Inventors: Yean-San Long, Hsinchu City (TW); Teng-Chun Wu, Kinmen County (TW); Cho-Fan Hsieh, Yilan County (TW); Shu-Tsung Hsu, Hsinchu City (TW); Chan-Hsiao Ho, Hsinchu County (TW)

(21) Appl. No.: 14/301,343

(22) Filed: Jun. 11, 2014

(30) Foreign Application Priority Data
Jul. 31, 2013 (TW) 102127499

(51) Int. Cl. G01R 31/40; G01N 21/95; G01R 31/26

(52) U.S. Cl. CPC H02S 50/00; G01R 31/2603; G01N 21/95
USPC 702/183

(57) ABSTRACT

A method and a system for inspecting a defect of a solar cell are provided, and the method includes: receiving inspecting data corresponding to the solar cell from an inspecting device; obtaining a current-voltage (I-V) curve of the solar cell according to the inspecting data; defining a first reference region on the I-V curve, and obtaining a plurality of first curve characteristics of the I-V curve in the first reference region; determining a defect type of the solar cell according to the first curve characteristics.

### CROSS-REFERENCE TO RELATED APPLICATION

This application claims the priority benefit of Taiwan application serial no. 102127499, filed on Jul. 31, 2013. The entirety of the above-mentioned patent application is hereby incorporated by reference herein and made a part of this specification.

### BACKGROUND

1. Technical Field

The disclosure relates to a method for inspecting defects of a solar cell and a system thereof.

2. Description of Related Art

Currently, countries around the world are actively developing for materials of solar cells and technologies for making the same, especially in development of a high effective Nano-scale solar cell and a material applied by such solar cell. In addition, solar cells with composite design such as a metallization-wrap-through (MWT) solar cell and an organic-type photovoltaic (OPV) solar cell have also been proposed. Materials and device structures of above-said solar cells are no longer limited to only one single material or a single layer structure.

At this stage, technology for inspecting defects of a solar cell is mainly relied on optical inspecting technologies. For instance, the optical inspecting technologies include electroluminescence (EL) and photoluminescence (PL). However, for solar cells composed of multiple materials or multi-layers, whether the defects of said solar cells can be rapidly and effectively inspected, is still an important research topic for person skilled in the art to work on.

### SUMMARY

The disclosure is directed to a method for inspecting defects of a solar cell and a system thereof, capable of performing analysis in multi-directions so as locate defects possibly existed in the solar cell.

The disclosure provides a method for inspecting defects of a solar cell, and the method includes: receiving inspecting data corresponding to the solar cell from an inspecting device; obtaining a current-voltage curve of the solar cell according to the inspecting data; defining a first reference region on the current-voltage curves, and obtaining a plurality of first curve characteristics of the current-voltage curve in the first reference region; and determining a defect type of the solar cell according to the first curve characteristics.

In addition, the disclosure further provides a system for inspecting defects of a solar cell, the system includes an inspecting device and an analyzing device. The inspecting device is configured to inspect a solar cell. The analyzing device is coupled to the inspecting device, and configured to receive inspecting data corresponding to the solar cell from an inspecting device. The analyzing device includes a curve obtaining module, a curve characteristic checking module and a defect checking module. The curve obtaining module is configured to obtain a current-voltage curve of the solar cell according to the inspecting data. The curve characteristic checking module is coupled to the curve obtaining module. The curve characteristic checking module is configured to define a first reference region on the current-voltage curves, and obtain a plurality of first curve characteristics of the current-voltage curve in the first reference region. The defect checking module is coupled to curve characteristic checking module, and configured to determine the defect type of the solar cell according to the first curve characteristics and the second curve characteristics.

Based on above, after the inspecting data corresponding to the solar cell is obtained, the disclosure is capable of obtaining the current-voltage curve of the solar cell according to the inspecting data. Next, the first reference region is defined on the current-voltage curves, and the first curve characteristics of the current-voltage curve in the first reference region are obtained. Next, the defect type of the solar cell is determined according to the first curve characteristics. Accordingly, the disclosure is capable of rapidly and accurately inspecting the defects possibly existed in the solar cell.

To make the above features and advantages of the disclosure more comprehensible, several embodiments accompanied with drawings are described in detail as follows.

### BRIEF DESCRIPTION OF THE DRAWINGS

FIG. 1 illustrates a system for inspecting defects of a solar cell according to an exemplary embodiment of the present disclosure.

FIG. 2 and FIG. 3 are schematic diagrams illustrating a current-voltage curve according to an exemplary embodiment of the present disclosure.

FIG. 4 and FIG. 5 are schematic diagrams illustrating a photoelectric conversion efficiency-spectrum curve according to an exemplary embodiment of the present disclosure.

FIG. 6 is a schematic diagram illustrating a solar cell according to an exemplary embodiment of the present disclosure.

FIG. 7 and FIG. 8 are schematic diagrams illustrating an equivalent circuit of the solar cell according to an exemplary embodiment of the present disclosure.

FIG. 9 is flowchart illustrating a method for inspecting defects of a solar cell according to an exemplary embodiment of the present disclosure.

FIG. 10 is flowchart illustrating a method for inspecting defects of a solar cell according to another exemplary embodiment of the present disclosure.

### DETAILED DESCRIPTION

Generally, besides breakages and cracks on a surface of a solar cell, parts of defects of the solar cell may also be hidden in an inner structure of the solar cell. For instance, there can be improper contacts such as moisture entering inside of the solar cell or between multiple layers of the solar cell, and so on. However, for various defects located/not located on the surface of the solar cell, currently, it still lacks a mechanism for rapidly, accurately and comprehensively inspecting the defects.

Therefore, the present disclosure provide a method for inspecting defects of a solar cell which is capable of determining a defect type of the solar cell according to a current-voltage curve of the solar cell and a photoelectric conversion efficiency of the solar cell in respond to a plurality of light rays having different wavelengths. Particularly, the method proposed in the disclosure not only can inspect the defects on the surface of the solar cell, but the defects existed inside of the solar cell can also be identified.

In addition, the present exemplary embodiment further discloses a system for inspecting defects of the solar cell. In order to make content of the present disclosure more comprehensible, exemplary embodiments are described below as the examples to prove that the present disclosure can actually be realized.

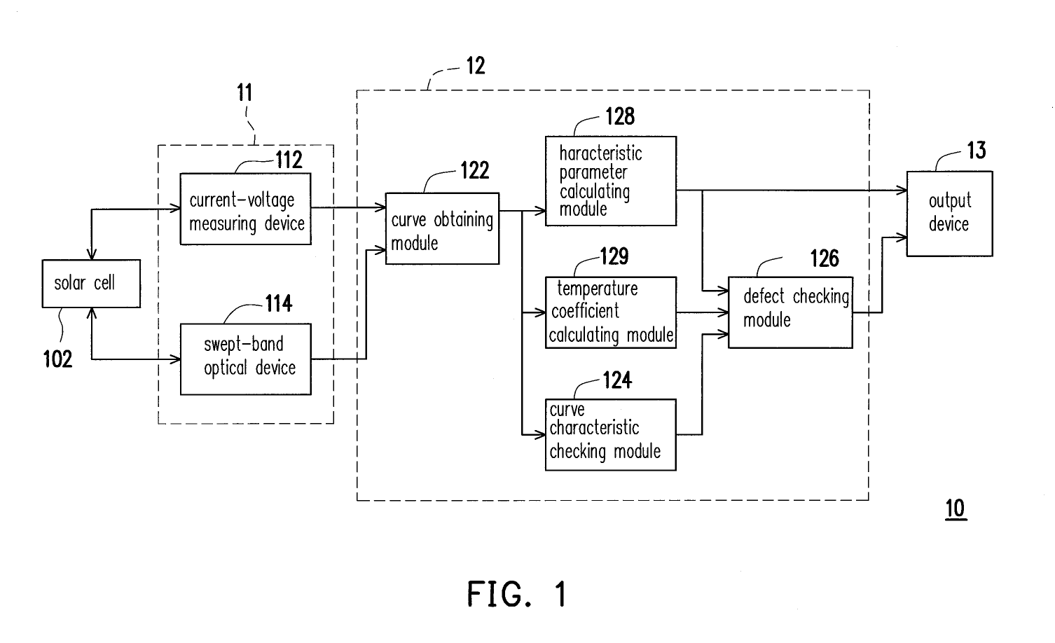

FIG. 1 illustrates a system for inspecting defects of a solar cell according to an exemplary embodiment of the present disclosure. Referring to FIG. 1, a system 10 for inspecting defects of the solar cell includes an inspecting device 11, an analyzing device 12 and an output device 13.

The inspecting device 11 is configured to inspect a solar cell 102. In the present exemplary embodiment, the inspecting device 11 includes a current-voltage measuring device 112 and a swept-band optical device 114. The current-voltage measuring device 112 is configured to perform an electrical inspection to the solar cell 102. For instance, the current-voltage measuring device 112 may include various metal reflectors such as an aluminum reflector, and may at least be configured to measure an input voltage and an output voltage of the solar cell 102.

The swept-band optical device 114 is configured to perform an optical inspection to the solar cell 102. For instance, the swept-band optical device 114 may be various swept-band optical device for generating light rays having different wavelengths such as a LED solar simulator or a monochromator. In other words, when the swept-band optical device 114 irradiates the light rays having different wavelengths to the swept-band optical device 102, the current-voltage measuring device 112 may measure the output voltage and the input voltage generated by the solar cell 102 in respond to the light rays having different wavelengths.

In addition, the inspecting device 11 may further provides an inspecting environment, so that the solar cell 102 can be inspected in the inspecting environment, and the inspecting device 11 can also control a temperature and a moisture of the inspecting environment. In other words, the inspecting environment simulated by the inspecting device 11 is similar to that of a black box, and the temperature and the moisture in the inspecting environment may also be adjusted arbitrarily by the a controller (not illustrated) of the inspecting device 11. Accordingly, the inspecting device 11 may comprehensively collect parameters including the output voltage and the input voltage generated by the solar cell 102 in respond to the light rays having different wavelengths under various temperatures, moistures and illuminations, as well as other parameters regarding a photoelectric conversion efficiency of the solar cell 102 being measured, and transmit above-said parameters to the analyzing device 12.

The analyzing device 12 is coupled to the inspecting device 11. The analyzing device 12 is configured to receive inspecting data corresponding to the solar cell 102 from the inspecting device 11, and obtain a current-voltage curve (I-V curve) of the solar cell 102 according to the inspecting data. Next, a defect type of the solar cell 102 may be determined by the analyzing device 12 according to the current-voltage curve being obtained. For instance, the analyzing device 12 may be various electronic devices with computing capabilities, such as a desktop PC, a notebook PC and a tablet PC. The analyzing device 12 may further include a storage unit, such as a hard drive (not illustrated) or a memory (not illustrated). The hard drive or the memory is built with a defect characteristic database which is stored with a plurality of defect characteristics in which each of the defect characteristics is corresponding to one of common defects of the solar cell. When the current-voltage curve of the solar cell 102 is obtained by the analyzing device 12, the analyzing device 12 compares the current-voltage curve with said defect characteristics, and determines a possible defect type of the solar cell 102 according to a comparison result. In the present exemplary embodiment, the defect type of the solar cell includes defects such as a lattice defect, a non-lattice plane defect, an electrode defect, a large-crack defect, a micro-crack defect, an inclusion defect, a moisture defect and a material defect, but the disclosure is not limited thereto.

The output device 13 is coupled to the analyzing device 12 and configured to present an analyzed result of the analyzing device 12. For instance, the output device 13 may include a video output device such as a display (not illustrated), and information regarding the defect type or property of the solar cell 102 determined by the analyzing device 12 may be displayed on the video output device. Or, in another exemplary embodiment, the output device 13 may further include an audio output device such as a speaker (not illustrated), so that the information regarding the defect type or property of the solar cell 102 can be outputted by voice.

More specifically, the analyzing device 12 includes a curve obtaining module 122, a curve characteristic checking module 124 and a defect checking module 126.

The curve obtaining module 122 receives the inspecting data from the inspecting device 11, and obtains the current-voltage (I-V) curve of the solar cell 102 according to the parameters such as the current and the voltage in the inspecting data.

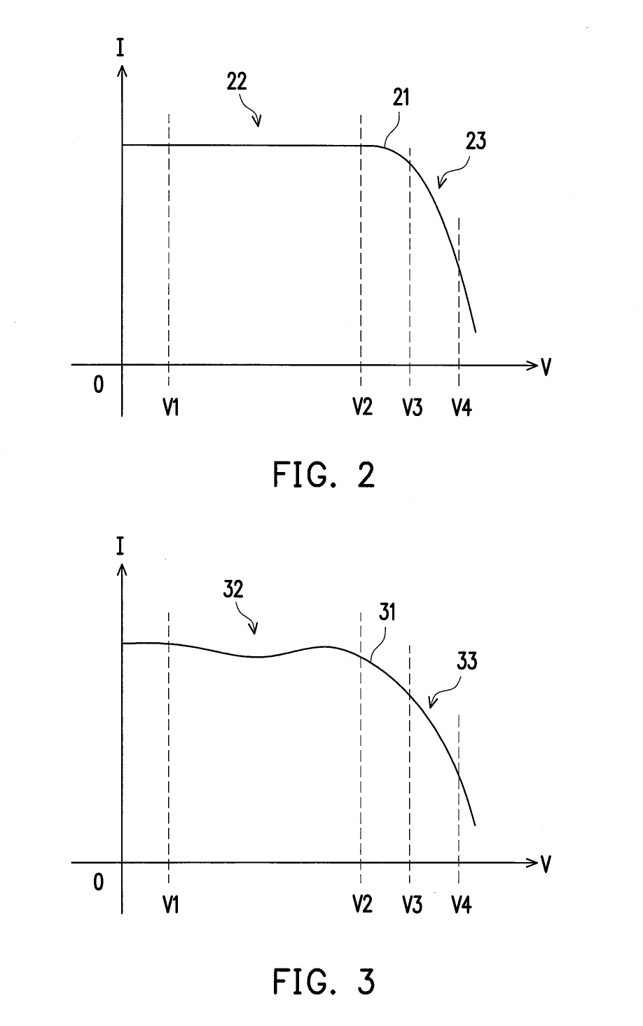

For instance, FIG. 2 and FIG. 3 are schematic diagrams illustrating a current-voltage curve according to an exemplary embodiment of the present disclosure. Referring to FIG. 2, in case the solar cell 102 has no substantial defects, the curve obtaining module 122, for example, generates a current-voltage curve 21. Otherwise, referring to FIG. 3, in case the solar cell 102 has substantial defects, the curve obtaining module 122, for example, generates a current-voltage curve 31 or similar curves. It should be noted that, the current-voltage curve 21 and the current-voltage curve 31 are merely examples and not intended to cover all possible conditions. The current-voltage curves actually being measured may be different in respond to different defects of the solar cell.

More specifically, the curve obtaining module 122 obtains an initial current-voltage curve of the solar cell 102 according to the inspecting data being received. However, the initial current-voltage curve may not have any analytical value if there is a problem in contact points of the solar cell 102 with wires, metal electrodes or other elements, or there is a problem in the packaging structure of the solar cell. For instance, if there is a problem in the contact points of the solar cell 102 with wires, metal electrodes or other elements, the inspecting data corresponding to the solar cell 102 cannot reflect real problems of the solar cell 102. Further, if there is a problem in the packaging structure of the solar cell 102, real defects of the solar cell 102 cannot be informed of through the current-voltage curve either.

Therefore, after the initial current-voltage curve is obtained by the curve obtaining module 122, the curve obtaining module 122 determines whether the initial current-voltage curve has a contact point defect characteristic or a packaging defect characteristic. Therein, the contact point defect characteristic and the packaging defect characteristic can both be quickly identified according to the initial current-voltage curve. For instance, the contact point defect characteristic is, for example, a current or a voltage in the initial current-voltage curve being too small, or a curve with dramatical variation. The packaging defect characteristic can be, for example, a bad packaging which leads to a variation of a capacitance effect being too obvious on the current-voltage curve. Therefore, if the initial current-voltage curve has one of the contact point defect characteristic or the packaging defect characteristic, this indicates that there is a problem in the contact points or the packaging structure of the solar cell 102, which requires no further inspections. Otherwise, if the initial current-voltage curve does not have the contact point defect characteristic and the packaging defect characteristic, the curve obtaining module 122 performs a smooth process to the initial current-voltage curve, so as to generate the current-voltage curve for subsequent analysis.

For instance, the initial current-voltage curve without processed by the smooth process can be, obviously, a ladder curve which may further include an obvious surge therein. Therefore, the smooth process as mentioned above is mainly used for correcting the ladder curve into a smoother curve, and smoothing the surge which is possibly provided on the ladder curve, so as to prevent accuracy of the subsequent analysis from being influenced.

The curve characteristic checking module 124 is coupled to the curve obtaining module 122. More specifically, the curve characteristic checking module 124 defines one or more reference curve ranges on the current-voltage curve generated by the curve obtaining module 122, and calculates a plurality of curve characteristics of the current-voltage curve within the one or more reference curve ranges. Take FIG. 3 as an example, the curve characteristic checking module 124 defines a reference curve range 32 (e.g., a range from a voltage V1 to a voltage V2, also known as a first reference region) on the current-voltage curve 31. Next, the curve characteristic checking module 124 calculates the curve characteristics such as a curvature radius or a slope corresponding to a plurality of voltage points on the current-voltage curve 31 within the reference curve range 32. Or, the curve characteristic checking module 124 also defines both the reference curve range 32 (e.g., the range from the voltage V1 to the voltage V2) and a reference curve range 33 (e.g., a range from a voltage V3 to a voltage V4, also known as a second reference region) on the current-voltage curve 31. Next, the curve characteristics such as the curvature radius or the slope corresponding to the voltage points on the current-voltage curve are calculated within the reference curve range 33 and the reference curve range 34. In the present exemplary embodiment, the number of the voltage points can be 3 to 10 or even more, based on actual requirements.

The defect checking module 126 analyzes said curve characteristics. For instance, the defect checking module 126 compares the curve characteristics with the curve characteristics in the defect characteristic database. If the curve characteristics are identical to a specific curve characteristic in the defect characteristic database, the defect checking module 126 determines the defect type of the solar cell 102 according to the specific defect characteristic.

Take FIG. 2 as an example, in case a reference curve range 22 (e.g., the range from the voltage V1 to the voltage V2) and a reference curve range 23 (e.g., a range from a voltage V3 to a voltage V4) are both defined on a current-voltage curve 21, within the reference curve range 22 and the reference curve range 23, the curvature radius and the slope of the current-voltage curve 21 are tended to remain unchanged. More specifically, within the reference curve range 22, the curvature radius of the current-voltage curve 21 is tended to approach infinity (or the slope of the current-voltage curve 21 is tended to approach zero), whereas within the reference curve range 23, the curvature radius or the slope of the current-voltage curve 21 are tended to approach infinity. Therefore, in case a plurality of curve characteristics of the current-voltage curve 21 within the reference curve range 22 (or both the reference curve range 22 and the reference curve range 23) are served as a basis of determining whether the solar cell has the defects, after a plurality of curve characteristics of the current-voltage curve 32 within the reference curve range 32 (or both the reference curve range 32 and the reference curve range 33) are compared with the curve characteristics of the current-voltage curve 21 within the reference curve range 22 (or both the reference curve range 22 and the reference curve range 23), the defect checking module 126 quickly is informed of whether the solar cell 102 has the defects. Next, by looking up the defect characteristic database, the defect checking module 126 further is informed of the defect type corresponding to the current-voltage curve (e.g., the current-voltage curve 31) currently obtained.

However, it should be noted that, the curvature radius and the slope of the current-voltage curve 21 served as the basis in FIG. 2 are merely an example, and the disclosure is not limited thereto. For instance, in other exemplary embodiments, an optimal condition for the curvature radius and the slope of the current-voltage curve may still be configured based on the actual requirements.

In order to comprehensively inspect the defect possibly existed in the solar cell, in an exemplary embodiment, the curve obtaining module 122 may also obtain a photoelectric conversion efficiency-spectrum curve according to the current, the voltage and the other parameters regarding the photoelectric conversion efficiency of the solar cell 102 in the inspecting data, and the photoelectric conversion efficiency-spectrum curve may present the photoelectric conversion efficiency of the solar cell 102 in respond to the light rays having different wavelengths.

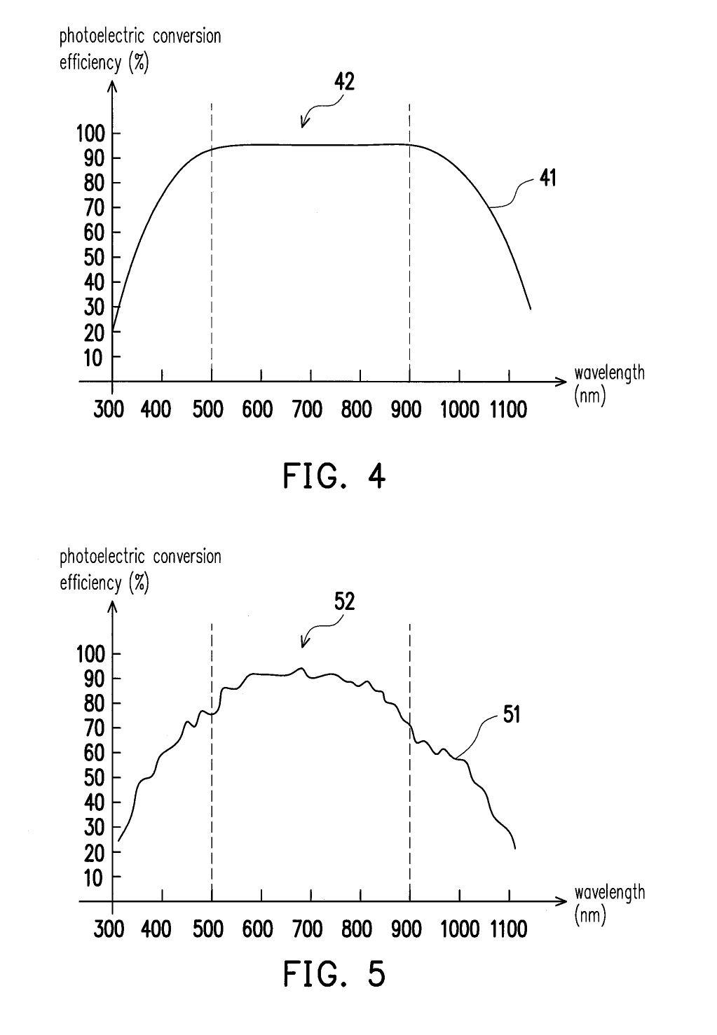

For instance, FIG. 4 and FIG. 5 are schematic diagrams illustrating a photoelectric conversion efficiency-spectrum curve according to an exemplary embodiment of the present disclosure. Referring to FIG. 4, in case the solar cell 102 has no substantial defects, the curve obtaining module 122, for example, generates a photoelectric conversion efficiency-spectrum curve 41 according to the inspecting data being received. In the present exemplary embodiment, the photoelectric conversion efficiency-spectrum curve 41 presents, for example, the photoelectric conversion efficiency of the solar cell 102 in respond to each of the light rays having wavelengths between 300 nm (nanometer) to 1100 nm. Otherwise, referring to FIG. 5, in case the solar cell 102 has substantial defects, the curve obtaining module 122, for example, generates a photoelectric conversion efficiency-spectrum curve 51 or similar curves. It should be noted that, the photoelectric conversion efficiency-spectrum curve 41 and the photoelectric conversion efficiency-spectrum curve 51 are merely examples and not intended to cover all possible conditions. The photoelectric conversion efficiency-spectrum curves actually being measured may be different in respond to different defects of the solar cell.

More specifically, the curve obtaining module 122 calculates a plurality of effective proportions of the light rays having different wavelengths and being irradiated on the solar cell 102 according to the inspecting data received, in which each of the effective proportions corresponds to one of the light rays having different wavelengths and being irradiated on the solar cell 102. It case the solar cell 102 is irradiated by the light ray with a specific wavelength, the solar cell 102 counts the number of effective solar chips in the solar cell 102, so as to obtain the photoelectric conversion efficiency of the solar cell 102 corresponding to the light ray having the specific wavelength. Therein, the effective solar chip refers a solar chip in the solar cell 102 which has the photoelectric conversion efficiency in respond to the light ray having the specific wavelength exceeding a conversion efficiency threshold value.

Based on above, in case the solar cell 102 is irradiated by of the light rays having K number (K being greater than 1) of light rays having different wavelengths, the curve obtaining module 122 counts the number of the solar chips (also known as a N-th number) having the photoelectric conversion efficiency in respond to the light ray having a specific wavelength (also known as a N-th wavelength, in which N is a positive integer from 1 to K) among the K number of light rays exceeding the conversion efficiency threshold value, and an effective proportion (also known as a N-th effective proportion) can be calculated according to the N-th number. For instance, the N-th effective proportion may be obtained by dividing the number of the effective solar chips in the solar cell 102 corresponding to the N-th wavelength, with a number of all the solar chips in the solar cell 102. Accordingly, after above calculations are completed for a K number of times (corresponding to the K number of light rays), the curve obtaining module 122 obtains a K number of effective proportions (also known as a first effective proportion to a K-th effective proportion), and the photoelectric conversion efficiency-spectrum curve (e.g., the photoelectric conversion efficiency-spectrum curve 41 or the photoelectric conversion efficiency-spectrum curve 51) may be obtained according to the K number of the effective proportions.

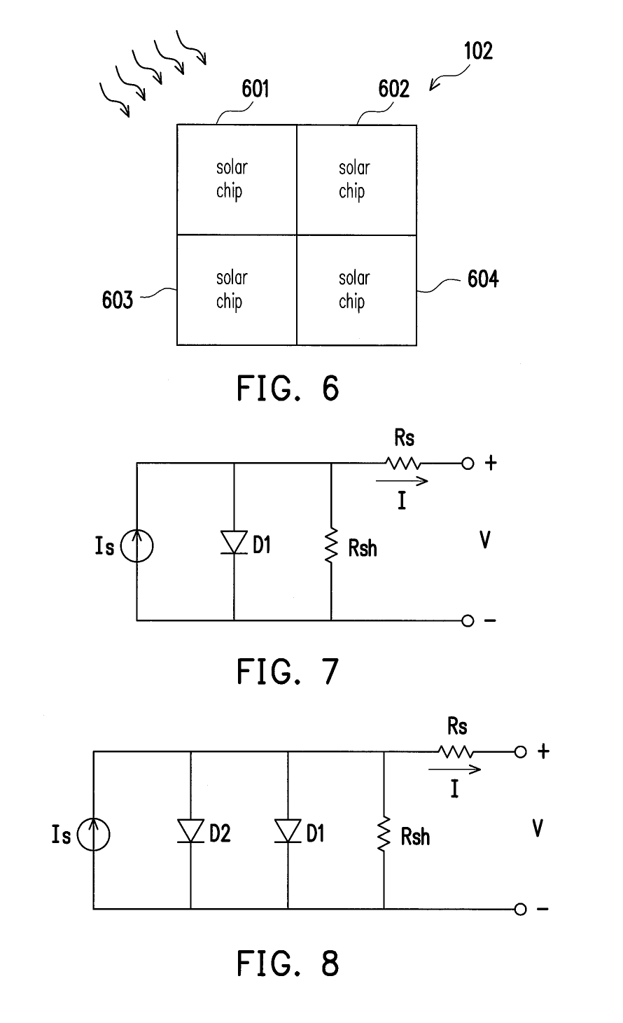

For instance, FIG. 6 is a schematic diagram illustrating a solar cell according to an exemplary embodiment of the present disclosure. Referring to FIG. 6, take K=2 as an example, (e.g., a first wavelength=600 nm, and a second wavelength=700 nm), in which the conversion efficiency threshold value is 90%, and the solar cell 102 includes solar chips 601 to 604, however, the disclosure is not limited thereto.

In case the inspecting device 11 (or the swept-band optical device 114) irradiates a light ray having the wavelength of 600 nm to the solar chips 601 to 604, and according to the inspecting data received, the curve obtaining module 122 obtains the photoelectric conversion efficiency of the solar chip 601 being 92%, the photoelectric conversion efficiency of the solar chip 602 being 88%, the photoelectric conversion efficiency of the solar chip 603 being 86% and the photoelectric conversion efficiency of the solar chip 604 being 94%. Further, in case the inspecting device 11 (or the swept-band optical device 114) irradiates a light ray having the wavelength of 700 nm to the solar chips 601 to 604, and according to the inspecting data received, the curve obtaining module 122 obtains the photoelectric conversion efficiency of the solar chip 601 being 93%, the photoelectric conversion efficiency of the solar chip 602 being 91%, the photoelectric conversion efficiency of the solar chip 603 being 89% and the photoelectric conversion efficiency of the solar chip 604 being 97%.

Next, for the light ray having the wavelength of 600 nm, the curve obtaining module 122 is informed that the number of solar chips having the photoelectric conversion efficiency greater than 90% (i.e., the conversion efficiency threshold value) in the solar cell 102 is 2 (i.e., the solar chip 601 and the solar chip 602), such number is 50% of the number of all of the solar chips 601 to 604. Further, for the light ray having the wavelength of 700 nm, the curve obtaining module 122 is informed that the number of solar chips having the photoelectric conversion efficiency greater than 90% in the solar cell 102 is 3 (i.e., the solar chip 601, the solar chip 602 and the solar chip 604), such number is 75% of the number of all of the solar chips 601 to 604.

In other words, in case the conversion efficiency threshold value is set to 90%, when the light ray having the wavelength of 600 nm is irradiated on the solar cell 102, the effective proportion of the solar chips 601 to 604 in the solar cell 102 is 50%. Further, when the light ray having the wavelength of 700 nm is irradiated on the solar cell 102, the effective proportion of the solar chips 601 to 604 in the solar cell 102 is 75%. Therefore, take FIG. 4 and FIG. 5 as an example, the curve obtaining module 122 can set N as 300 to 1100, and repeats above operations, so as to obtain the photoelectric conversion efficiency-spectrum curve 41 and the photoelectric conversion efficiency-spectrum curve 51.

Next, based on the defect type previously determined by the current-voltage curve, the defect checking module 126 performs a double verification to said defect type by utilizing the photoelectric conversion efficiency-spectrum curve, or correct the defect type previously determined by the current-voltage curve.

For instance, the curve characteristic checking module 124 may also define a reference curve range on the photoelectric conversion efficiency-spectrum curve generated by the curve obtaining module 122, and calculate a plurality of curve characteristics of the photoelectric conversion efficiency-spectrum curve within the reference curve range. Take FIG. 5 as an example, the curve characteristic checking module 124 can define a reference curve range 52 (e.g., a range from a wavelength of 500 to a wavelength of 900) on the photoelectric conversion efficiency-spectrum curve 51. Next, the curve characteristic checking module 124 can calculate curve characteristics such as a curvature radius or a slope corresponding to a plurality of reference points on the photoelectric conversion efficiency-spectrum curve 51 within the reference curve range 52. Next, the defect checking module 126 compares the curve characteristics with the curve characteristics in the defect characteristic database. If the curve characteristics are identical to a specific curve characteristic in the defect characteristic database, the defect checking module 126 determines the defect type of the solar cell 102 according to the specific defect characteristic. In the present exemplary embodiment, a number of the reference points can be 3 to 10 or even more, depending on actual requirements.

Take FIG. 4 as an example, in case a reference curve range 42 (e.g., the range from the wavelength of 500 to the wavelength of 900) is defined on the photoelectric conversion efficiency-spectrum curve 41, within the reference curve range 42, the curvature radius and the slope of each reference point on the photoelectric conversion efficiency-spectrum curve 41 are tended to remain unchanged. More specifically, within the reference curve range 42, the curvature radius of each reference point of the photoelectric conversion efficiency-spectrum curve 41 is tended to approach infinity (or the slope is tended to approach zero). Therefore, in case a plurality of curve characteristics of the photoelectric conversion efficiency-spectrum curve 41 within the reference curve range 42 are served as a basis of determining whether the solar cell has the defects, after a plurality of curve characteristics of the photoelectric conversion efficiency-spectrum curve 51 within the reference curve range 52 are compared with the curve characteristics of the photoelectric conversion efficiency-spectrum curve 41 within the reference curve range 42, the defect checking module 126 quickly is informed of whether the solar cell 102 has the defects. Next, by looking up the defect characteristic database, the defect checking module 126 further is informed of the defect type corresponding to the photoelectric conversion efficiency-spectrum curve (e.g., the photoelectric conversion efficiency-spectrum curve 41) currently obtained.

However, it should be noted that, the curvature radius and the slope of the photoelectric conversion efficiency-spectrum curve 41 served as the basis in FIG. 4 are merely an example, and the disclosure is not limited thereto. For instance, in other exemplary embodiments, an optimal condition for the curvature radius and the slope of the photoelectric conversion efficiency-spectrum curve can still be configured based on the actual requirements.

In summary, the present disclosure is capable of locating relations and regulations of the defects possibly existed in the solar cell, the current-voltage curve and the photoelectric conversion efficiency-spectrum curve, so that the defects possibly existed in the solar cell can be identified based on identification regulations according to the current-voltage curve and the photoelectric conversion efficiency-spectrum curve.

From another perspective, the defect checking module 126 may determine an electrical defect according to the current-voltage curve, and determine a spectrum defect of the solar cell according to the photoelectric conversion efficiency-spectrum curve. For instance, the electrical defect may include the lattice defect, the non-lattice plane defect, the electrode defect, the large-crack defect, the micro-crack defect, the inclusion defect and the moisture defect, and the spectrum defect may include the large-crack defect, the micro-crack defect, the inclusion defect and the material defect, but the disclosure is not limited thereto.

FIG. 7 and FIG. 8 are schematic diagrams illustrating an equivalent circuit of the solar cell according to an exemplary embodiment of the present disclosure. Referring to FIG. 7, it is assumed that the solar cell is considered as a diode D1, an equivalent circuit 71 of the solar cell generates a series resistor Rₛ and a parallel resistor Rₛₕ due to a parasitics effect. The parallel resistor Rₛₕ is generated mainly by a leakage current of the solar cell or defects related to the lattice, and the series resistor Rₛ is caused by, for example, contact resistors, metal electrodes or wires. Generally, in case the solar cell has no substantial defects, the parallel resistor Rₛₕ is fairly big, so that a conductivity between electrons and electron holes in the solar cell (i.e., the diode D1) cannot be lost. For instance, in case the solar cell has substantial defects, a current I that flowed through the series resistor Rₛ can be represented by the following equation (1.1)

$$I = {I}_{s} [ exp ( \frac{qV}{kT} ) - 1 ] - {I}_{sh} \qquad ( 1 \text{-} 1 )$$

Therein, q is an electric quantity unit, k is a Boltzmann constant, T is an absolute temperature, and Iₛ is a saturation current.

Otherwise, referring to FIG. 8, in case the solar cell has cracks or similar defects, the cracks or the similar defects are deemed as a diode D2 in an equivalent circuit 81 of the solar cell. With respect to FIG. 7, the current originally flowed through the diode D1 is partially changed to flow through the diode D2 (i.e., the leakage current is generated). In this case, the current I flowed through the series resistor Rₛ can be represented by the following equation (1.2):

$$I = {I}_{s} [ exp ( \frac{qV}{kT} ) - 1 ] - {I}_{sh} - {I}_{sh , D 2} \qquad ( 1 \text{-} 2 )$$

Therein, I_{sh,D2} represents the current (i.e., the leakage current) flowed through the diode D2. Take a conventional crystalline silicon solar cell as an example, in which type of the electrical defect of said solar cell can be mainly classified into a lattice defect and a non-lattice plane defect. The lattice defect can be, for example, a discontinuity on a structure inside of the solar cell where an impurity is existed therein. The non-lattice plane defect is, for example, cracks caused by external force, and a leakage path is formed at the cracks. The lattice defect usually causes Rₛ to generate a variation being relatively greater, and the non-lattice plane defect usually causes Rₛₕ to generate a variation being relatively greater. Furthermore, take FIG. 3 as an example, the variation generated by Rₛ is usually within the reference curve range 23, and the variation generated by Rₛₕ is usually within the reference curve range 22. Accordingly, by analyzing the current-voltage curve, the defect checking module 126 can be informed of degrees of the variations generated by Rₛ and/or Rₛₕ, or other defect characteristics regarding the electrical defects as mentioned above.

Further, the defect checking module 126 determines whether the photoelectric conversion efficiency-spectrum curve of the solar cell 102 is smooth and stabilized. In case the photoelectric conversion efficiency-spectrum curve of the solar cell 102 is not smooth or not stabilized, the defect checking module 126 further analyzes that the photoelectric conversion efficiencies of the solar cell 102 with worse efficiency are in respond to light rays having which wavelengths, or determines that the photoelectric conversion efficiency-spectrum curves of the solar cell 102 with greater undulations are in respond to light rays within which wavelength ranges. Next, the defect checking module 126 looks up the defect characteristic database according to the analyzed result being obtained, so as to obtain the spectrum defect, correspondingly.

Next, after the electrical defect and the spectrum defect possibly existed in the solar cell 102 is determined, the defect checking module 126 relates the electrical defect with the spectrum defect, and determines the defect type which is most likely existed in the solar cell 102 according to a relating result of relating the electrical defect with the spectrum defect. More specifically, the current-voltage curve is based on an electrical measurement being performed to the entire solar cell, thus the electrical defect is an inspecting result of a full inspection for the solar cell. In addition, the photoelectric conversion efficiency-spectrum curve is obtained by analyzing and counting the photoelectric conversion efficiency of the each solar chip in the solar cell, thus the spectrum defect is an inspecting result of a regional inspection for the solar cell. Therefore, the disclosure can provide both the full inspection and the regional inspection by utilizing the current-voltage curve and the photoelectric conversion efficiency-spectrum curve. In other words, with the double verification made to the defect type based on the current-voltage curve by utilizing the photoelectric conversion efficiency-spectrum curve, the disclosure can rapidly, accurately and comprehensively inspect whether the solar cell 102 has all sorts of defects such as the lattice defect, the non-lattice plane defect, the electrode defect, the large-crack defect, the micro-crack defect, the inclusion defect, the moisture defect and the material defect, and the defect type being identified can be presented to the developers as foundation for subsequent inspections and improvements to the defects.

However, the present disclosure is not limited thereto. Referring back to FIG. 1, in an exemplary embodiment, the analyzing device 12 can also include a characteristic parameter calculating module 128. More specifically, the characteristic parameter calculating module 128 is coupled to the curve obtaining module 122 and the defect checking module 126. The characteristic parameter calculating module 128 may execute a curve fitting calculation such as least square approximation, so as to obtain a polynomial fitting curve equation capable of representing the current-voltage curve of the solar cell 101. For instance, the characteristic parameter calculating module 128 determines whether a fitting error of the polynomial fitting curve equation is less than a preset value. In case the fitting error of the polynomial fitting curve equation is not less than a preset value, this indicates that the polynomial fitting curve equation is not capable of representing the current-voltage curve of the solar cell 101. Therefore, the characteristic parameter calculating module 128 adjusts a fitting parameter by, for example, adding 1 to a perfect power of the polynomial fitting curve equation, and executing the curve fitting calculation again, so as obtain another polynomial fitting curve equation.

In case the fitting error of the polynomial fitting curve equation is less than a preset value or meets a basic requirement, this indicates that the polynomial fitting curve equation is capable of representing the current-voltage curve, the current-voltage fitting curve, of the solar cell 101. Therefore, according to the polynomial fitting curve equation, the characteristic parameter calculating module 128 may calculate characteristic parameters of the equivalent circuit of the solar cell 102, such as open circuit voltage (Voc), short circuit current (Isc), maximum power (Pm), maximum power current (Imp) and maximum power voltage (Vmp), and transmit the calculated characteristic parameters to the defect checking module 126 for analysis.

Next, the defect checking module 126 determines the defect type of the solar cell 102 according to the current-voltage curve (or first curve characteristics), the photoelectric conversion efficiency-spectrum curve and the characteristic parameters.

In addition, in another exemplary embodiment, the analyzing device 12 may also include a temperature coefficient calculating module 129. The temperature coefficient calculating module 129 is coupled to the curve obtaining module 122 and the defect checking module 126. According to temperature coefficients related to the current-voltage curve and the photoelectric conversion efficiency-spectrum curves obtained under different temperatures and/or illuminances, the temperature coefficient calculating module 129 can output a temperature coefficient of the solar cell 102 corresponding to the different temperatures and/or the illuminances, to the defect checking module 126. Next, the defect checking module 126 determine the defect type of the solar cell 102 according to the current-voltage curve (or the first curve characteristics), the photoelectric conversion efficiency-spectrum curve, the characteristic parameters and the temperature coefficient.

In other words, during a process of analyzing the current-voltage curve and the photoelectric conversion efficiency-spectrum curve for the defects, the defect checking module 126 can also obtain more precise and complete information for the defects with references to data outputted by the characteristic parameter calculating module 128 and the temperature coefficient calculating module 129. For instance, by utilizing the characteristic parameters outputted by the characteristic parameter calculating module 128 and the temperature coefficient outputted by the temperature coefficient calculating module 129, the defect checking module 126 is informed of auxiliary information such as variations of the current-voltage curve and the photoelectric conversion efficiency-spectrum curve under the different temperatures and/or the illuminances as well as the open circuit voltage and the short circuit current in detail, so as to facilitate in subsequent analysis.

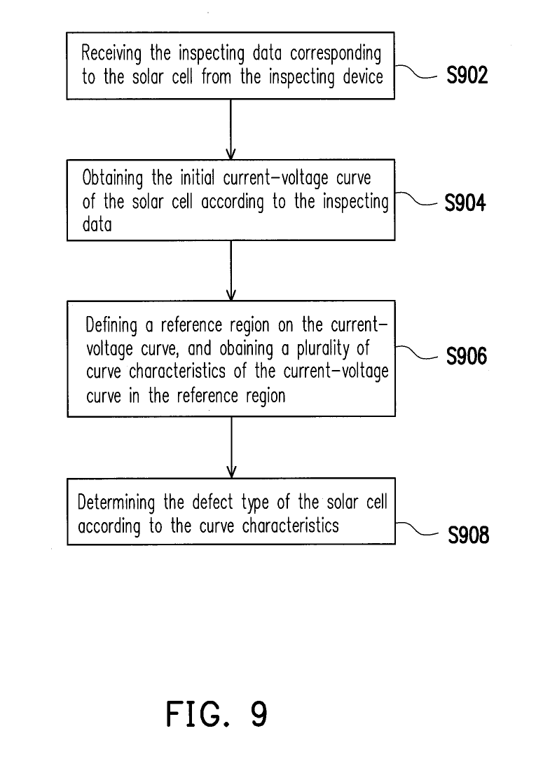

FIG. 9 is flowchart illustrating a method for inspecting defects of a solar cell according to an exemplary embodiment of the present disclosure.

Referring to FIG. 1 and FIG. 9 together, in step S902, the analyzing device 12 (or the curve obtaining module 122) receives the inspecting data corresponding to the solar cell 102 from the inspecting device 11.

Next, in step S904, the curve obtaining module 122 obtains the initial current-voltage curve of the solar cell 102 according to the inspecting data. Next, in step S906, the curve characteristic checking module 124 defines a reference region on the current-voltage curve, and obtains a plurality of curve characteristics of the current-voltage curve in the reference region.

Next, in step 908, the defect checking module 126 determines the defect type which is most likely existed in the solar cell 102.

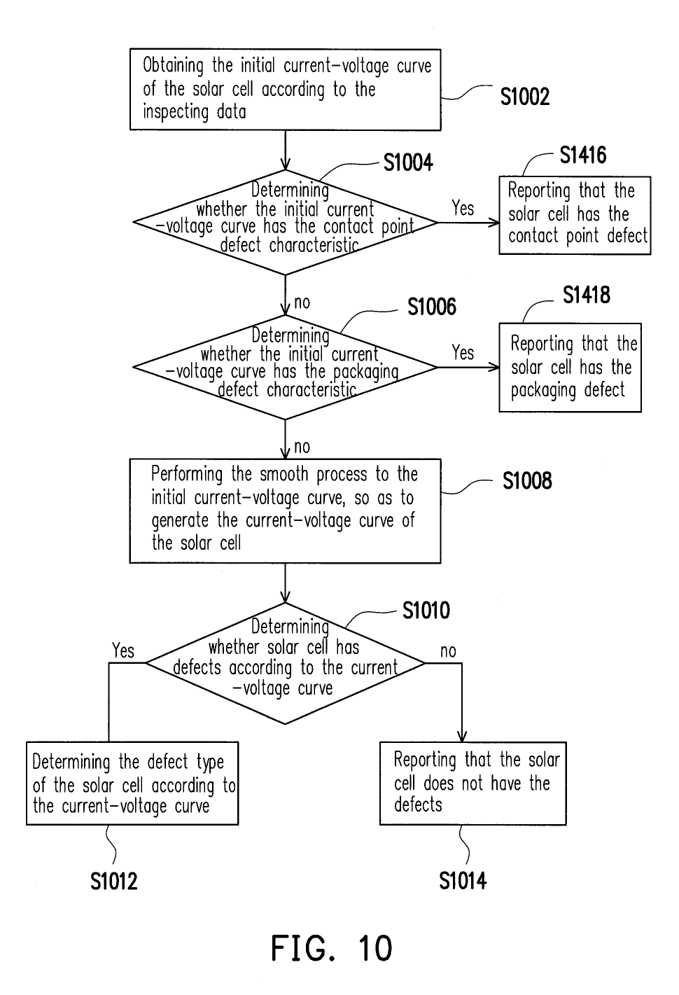

FIG. 10 is flowchart illustrating a method for inspecting defects of a solar cell according to another exemplary embodiment of the present disclosure.

Referring to FIG. 10, in step S1002, the curve characteristic checking module 124 obtains the initial current-voltage curve of the solar cell 102 according to the inspecting data. Next, in step S1004, the curve characteristic checking module 124 determines whether the initial current-voltage curve has the contact point defect characteristic.

If the initial current-voltage curve does not have the contact point defect characteristic, in step S1006, the curve characteristic checking module 124 determines whether the initial current-voltage curve has the packaging defect characteristic.

Otherwise, if the initial current-voltage curve does not have the packaging defect characteristic either, in step S1008, the curve characteristic checking module 124 performs the smooth process to the initial current-voltage curve, so as to generate the current-voltage curve of the solar cell 102.

Next, in step S1010, the defect checking module 126 determines whether solar cell 102 has defects according to the current-voltage curve processed by the smooth process, for example, by comparing the curve characteristics of the current-voltage curve with the curve characteristics in the defect characteristic database.

In case the solar cell 102 has defects, in step S1012, the defect checking module 126 further determines the defect type which is most likely existed in the solar cell 102 according to the current-voltage curve. Otherwise, if the solar cell 102 does not have the defects, in step S1014, the defect checking module 126 reports that the solar cell 102 does not have the defects.

If it is determine in step S1014 that the initial current-voltage curve has the contact point defect characteristic, in step S1016, the defect checking module 126 reports that the solar cell 102 has the contact point defect, and no subsequent inspection is executed.

Similarly, if it determined in step S1016 that the initial current-voltage curve has the packaging defect characteristic, in step S1018, the defect checking module 126 reports that the solar cell 102 has the packaging defect, and no subsequent inspection is executed.

It should be noted that, step S1004 and step S1006 depicted in FIG. 10 can be executed simultaneously or sequentially, and an executing sequence thereof can also be adaptively adjusted. For instance, in another exemplary embodiment, step S1006 can first be executed. If a result of such determination is no, proceeding to step S1004. In addition, detailed implementations regarding the method above have been fully disclosed in the previous exemplary embodiments, thus related description thereof is omitted hereinafter.

In addition, the curve obtaining module 122, the curve characteristic checking module 124, the defect checking module 126, the characteristic parameter calculating module 128 and the temperature coefficient calculating module 129 as mentioned in previous exemplary embodiments can be, for example, hardware devices or circuits composed of logic circuit components for executing above-said function, respectively. In addition, the curve obtaining module 122, the curve characteristic checking module 124, the defect checking module 126, the characteristic parameter calculating module 128 and the temperature coefficient calculating module 129 can also be implemented by, for example, software programs or firmware programs stored in the hard drive or the memory of the analyzing device 12. For instance, in an exemplary embodiment, the curve obtaining module 122, the curve characteristic checking module 124, the defect checking module 126, the characteristic parameter calculating module 128 and the temperature coefficient calculating module 129 can be loaded in a processor (not illustrated) of the analyzing device 12, so as to respectively execute each step in the method for inspecting defects of the solar cell.

In summary, the disclosure can obtain the related inspecting data according to the inspecting result of the inspections performed to the solar cell. Subsequently, according to the inspecting data, information such the current-voltage curve of the solar cell, the photoelectric conversion efficiency of the solar cell in respond to the light rays having different wavelengths, the characteristic parameters of the equivalent circuit of the solar cell and the temperature coefficient corresponding to the different temperatures and/or the illuminances, such that parts or all of the information can be utilized to determine the defect type which is most lily existed in the solar cell.

Although the present disclosure has been described with reference to the above embodiments, it is apparent to one of the ordinary skill in the art that modifications to the described embodiments may be made without departing from the spirit of the present disclosure. Accordingly, the scope of the present disclosure will be defined by the attached claims not by the above detailed descriptions.

Which is claimed is:

1. A method for inspecting defects of a solar cell, comprising:
receiving inspecting data corresponding to the solar cell from an inspecting device;
obtaining a current-voltage curve of the solar cell according to the inspecting data;
defining a first reference region on the current-voltage curve, and obtaining a plurality of first curve characteristics of the current-voltage curve in the first reference region; and
determining a defect type of the solar cell according to the first curve characteristics.

2. The method for inspecting defects of the solar cell as claimed in claim 1, wherein the inspecting data comprises an inspecting result of an electrical inspection and an inspecting result of an optical inspection, and the method for inspecting defects of solar cell further comprises:
performing the electrical inspection to the solar cell by a current-voltage measuring device of the inspecting device; and
performing the optical inspection to the solar cell by a swept-band optical device of the inspecting device.

3. The method for inspecting defects of the solar cell as claimed in claim 1, further comprising:
providing an inspecting environment by the inspecting device, inspecting the solar cell in the inspecting environment, and controlling a temperature and a moisture of the inspecting environment by the inspecting device.

4. The method for inspecting defects of the solar cell as claimed in claim 1, wherein obtaining the current-voltage curve of the solar cell according to the inspecting data, comprising:
obtaining an initial current-voltage curve of the solar cell according to the inspecting data;
determining whether the initial current-voltage curve has a contact point defect characteristic or a packaging defect characteristic; and
performing a smooth process to the initial current-voltage curve if the initial current-voltage curve has none of the contact point defect characteristic and the packaging defect characteristic, so as to generate the current-voltage curve.

5. The method for inspecting defects of the solar cell as claimed in claim 1, wherein determining the defect type of the solar cell according to the first curve characteristics, comprising:
defining a second reference region on the current-voltage curve, and obtaining a plurality of second curve characteristics of the current-voltage curve in the second reference region; and
determining the defect type of the solar cell according to the first curve characteristics and the second curve characteristics.

6. The method for inspecting defects of the solar cell as claimed in claim 1, wherein determining the defect type of the solar cell according to the first curve characteristics, comprising:
obtaining a photoelectric conversion efficiency-spectrum curve, wherein the photoelectric conversion efficiency-spectrum curve presents a photoelectric conversion efficiency of the solar cell in respond to a plurality of light rays having different wavelengths; and
determining the defect type of the solar cell according to the first curve characteristics and the photoelectric conversion efficiency-spectrum curve.

7. The method for inspecting defects of the solar cell as claimed in claim 6, further comprising:
calculating a plurality of effective proportions corresponding to the light rays having different wavelengths according to the inspecting data, wherein each of the effective proportions corresponds to one of the light rays having different wavelengths, and the effective proportion corresponding to the light ray having a N-th wavelength among the light rays having different wavelengths is obtained by dividing a number of a plurality of effective solar chips among a plurality of solar chips in the solar cell, with a number of the solar chips in the solar cell, wherein the photoelectric conversion efficiency of the effective solar chips in respond to the light ray having the N-th wavelength exceeds a conversion efficiency threshold value, wherein N is an integer not greater than the number of the light rays having different wavelengths; and
obtaining the photoelectric conversion efficiency-spectrum curve according to the effective proportions.

8. The method for inspecting defects of the solar cell as claimed in claim 6, wherein determining the defect type of the solar cell according to the first curve characteristics and the photoelectric conversion efficiency-spectrum curve, comprising:
determining an electrical defect of the solar cell according to the first curve characteristics;
determining a spectrum defect of the solar cell according to the photoelectric conversion efficiency-spectrum curve;
relating the electrical defect with the spectrum defect; and
determining the defect type of the solar cell according to a relating result of relating the electrical defect with the spectrum defect.

9. The method for inspecting defects of the solar cell as claimed in claim 6, wherein determining the defect type of the solar cell according to the first curve characteristics and the photoelectric conversion efficiency-spectrum curve, comprising:
executing a curve fitting to the inspecting data, so as to generate a current-voltage fitting curve;
obtaining at least one characteristic parameter of an equivalent circuit of the solar cell according to the current-voltage fitting curve; and
determining the defect type of the solar cell according to the first curve characteristics, the photoelectric conversion efficiency-spectrum curve and the at least one characteristic parameter of the equivalent circuit of the solar cell.

10. The method for inspecting defects of the solar cell as claimed in claim 9, wherein determining the defect type of the solar cell according to the first curve characteristics, the photoelectric conversion efficiency-spectrum curve and the at least one characteristic parameter of the equivalent circuit of the solar cell, comprising:
calculating a temperature coefficient of the solar cell corresponding to a plurality of different temperatures according to the inspecting data; and
determining the defect type of the solar cell according to the first curve characteristics, the photoelectric conversion efficiency-spectrum curve, the at least one characteristic parameter of the equivalent circuit of the solar cell and the temperature coefficient of the solar cell corresponding to the different temperatures.

11. The method for inspecting defects of the solar cell as claimed in claim 1, wherein the defect type of the solar cell includes a lattice defect, a non-lattice plane defect, an electrode defect, a micro-crack defect, an inclusion defect, a moisture defect and a material defect.

12. A system for inspecting defects of a solar cell, comprising:
an inspecting device configured to inspect the solar cell; and
an analyzing device coupled to the inspecting device, and configured to receive inspecting data corresponding to the solar cell from an inspecting device, wherein the analyzing device comprises:
a curve obtaining module configured to obtain a current-voltage curve of the solar cell according to the inspecting data;
a curve characteristic checking module coupled to the curve obtaining module, wherein the curve characteristic checking module is configured to define a first reference region on the current-voltage curve, and obtain a plurality of first curve characteristics of the current-voltage curve in the first reference region; and
a defect checking module coupled to curve characteristic checking module, and configured to determine a defect type of the solar cell according to the first curve characteristics.

13. The system for inspecting defects of the solar cell as claimed in claim 12, wherein the inspecting data comprises an inspecting result of an electrical inspection and an inspecting result of an optical inspection, and the inspecting device further comprises:
a current-voltage measuring device configured to perform an electrical inspection to the solar cell; and
a swept-band optical device configured to perform an optical inspection to the solar cell.

14. The system for inspecting defects of the solar cell as claimed in claim 12, wherein the inspecting device is further configured to provide an inspecting environment so that the solar cell is inspected in the inspecting environment, and the inspecting device is further configured to control a temperature and a moisture of the inspecting environment.

15. The system for inspecting defects of the solar cell as claimed in claim 12, wherein the curve obtaining module is further configured to obtain an initial current-voltage curve of the solar cell according to the inspecting data,
wherein the curve obtaining module is further configured to determine whether the initial current-voltage curve has a contact point defect characteristic or a packaging defect characteristic,
wherein the curve obtaining module is further configured to perform a smooth process to the initial current-voltage curve if the initial current-voltage curve has none of the contact point defect characteristic and the packaging defect characteristic, so as to generate the current-voltage curve.

16. The system for inspecting defects of the solar cell as claimed in claim 12, wherein the curve characteristic checking module is further configured to define a second reference region on the current-voltage curve, and obtain a plurality of second curve characteristics of the current-voltage curve in the second reference region,
wherein the defect checking module is further configured to determine the defect type of the solar cell according to the first curve characteristics and the second curve characteristics.

17. The system for inspecting defects of the solar cell as claimed in claim 12, wherein the curve obtaining module is further configured to obtain a photoelectric conversion efficiency-spectrum curve, wherein the photoelectric conversion efficiency-spectrum curve presents a photoelectric conversion efficiency of the solar cell in respond to a plurality of light rays having different wavelengths,
wherein the defect checking module is further configured to determine the defect type of the solar cell according to the first curve characteristics and the photoelectric conversion efficiency-spectrum curve.

18. The system for inspecting defects of the solar cell as claimed in claim 17, wherein the curve obtaining module is further configured to calculate a plurality of effective proportions corresponding to the light rays having different wavelengths according to the inspecting data, wherein each of the effective proportions corresponds to one of the light rays having different wavelengths, and the effective proportion corresponding to the light ray having a N-th wavelength among the light rays having different wavelengths is obtained by dividing a number of a plurality of effective solar chips among a plurality of solar chips in the solar cell, with a number of the solar chips in the solar cell, wherein the photoelectric conversion efficiency of the effective solar chips in respond to the light ray having the N-th wavelength exceeds a conversion efficiency threshold value, wherein N is an integer not greater than the number of the light rays having different wavelengths,
wherein the curve obtaining module is further configured to obtain the photoelectric conversion efficiency-spectrum curve according to the effective proportions.

19. The system for inspecting defects of the solar cell as claimed in claim 17, wherein the defect checking module is configured to determine the defect type of the solar cell according to the first curve characteristics,
wherein the defect checking module is further configured to determine a spectrum defect of the solar cell according to the photoelectric conversion efficiency-spectrum curve,
wherein the defect checking module is further configured to relate the electrical defect with the spectrum defect,
wherein the defect checking module is further configured to determine the defect type of the solar cell according to a relating result of relating the electrical defect with the spectrum defect.

20. The system for inspecting defects of the solar cell as claimed in claim 17, further comprising:
a characteristic parameter calculating module configured to execute a curve fitting to the inspecting data, so as to generate a current-voltage fitting curve,
wherein the characteristic parameter calculating module is further configured to obtain at least one characteristic parameter of an equivalent circuit of the solar cell according to the current-voltage fitting curve,
wherein the defect checking module is further configured to determine the defect type of the solar cell according to the first curve characteristics, the photoelectric conversion efficiency-spectrum curve and the at least one characteristic parameter of the equivalent circuit of the solar cell.

21. The system for inspecting defects of the solar cell as claimed in claim 20, further comprising:
a temperature coefficient calculating module configured to calculate a temperature coefficient of the solar cell corresponding to a plurality of different temperatures according to the inspecting data; and
wherein the defect checking module is further configured to determine the defect type of the solar cell according to the first curve characteristics, the photoelectric conversion efficiency-spectrum curve, the at least one characteristic parameter of the equivalent circuit of the solar cell and the temperature coefficient of the solar cell corresponding to the different temperatures.

22. The system for inspecting defects of the solar cell as claimed in claim 12, wherein the defect type of the solar cell includes a lattice defect, a non-lattice plane defect, an electrode defect, a micro-crack defect, an inclusion defect, a moisture defect and a material defect.
